(19) United States
(12) Patent Application Publication
(10) Pub. No.: US 2026/0331050 A1
(43) Pub. Date: Oct. 22, 2026

(54) DISPLAY DEVICE AND ELECTRONIC DEVICE INCLUDING THE SAME

(71) Applicant: Samsung Display Co., Ltd., Yongin-si (KR)

(72) Inventors: Gyeong-Ub MOON, Yongin-si (KR); Seunghun Moon, Yongin-si (KR); Kangbin Jo, Yongin-si (KR); Goeun Cha, Yongin-si (KR); Boram Choi, Yongin-si (KR)

(73) Assignee: Samsung Display Co., Ltd., Yongin-si (KR)

(21) Appl. No.: 19/529,481

(22) Filed: Feb. 4, 2026

(30) Foreign Application Priority Data
Mar. 31, 2025 (KR) 10-2025-0041719

(51) Int. Cl. G09G 3/3233; G06V 40/13

(52) U.S. Cl. CPC G09G 3/3233; G06V 40/1318; G09G 2300/0819; G09G 2300/0842; G09G 2300/0861; G09G 2310/08; G09G 2320/0238; G09G 2320/0257; G09G 2354/00

(57) ABSTRACT

A display device includes pixel circuits, sensor circuits, light emitting elements respectively connected to the pixel circuits, and light receiving elements respectively connected the sensor circuits. Each of the sensor circuits includes an output transistor operating in response to an output control signal and a control transistor operating in response to a light receiving control signal. An active period of the output control signal applied to at least one of the sensor circuits overlaps a non-active period of the light receiving control signal.

### CROSS-REFERENCE TO RELATED APPLICATIONS

This application claims priority to and the benefit of Korean Patent Application No. 10-2025-0041719, filed on Mar. 31, 2025 in the Korean Intellectual Property Office, the disclosure of which is incorporated by reference herein in its entirety.

### BACKGROUND

### Field

The disclosure relates to a display device and an electronic device including the same. More particularly, the disclosure relates to a display device with a biometric information recognition function and an electronic device including the display device.

### Descripion of Related Art

Display devices provide a variety of functions to interact with users, such as displaying images to provide information or detecting user inputs. Recently, the display devices have begun to incorporate features for detecting users’ biometric information.

As biometric information recognition methods, a capacitive method that detects variations in capacitance formed between electrodes, an optical method that detects incident light using an optical sensor, an ultrasonic method that detects vibrations using a piezoelectric material, or the like are used.

### SUMMARY

The disclosure provides a display device with an improved biometric information recognition function and an electronic device including the display device.

According to one or more embodiments, there is provided a display device which may include pixel circuits, sensor circuits, light emitting elements respectively connected to the pixel circuits, and light receiving elements respectively connected the sensor circuits. Each of the sensor circuits may include a sensing capacitor, a reset transistor connected between a reset voltage line and the first sensing node and operating in response to a reset control signal, an amplification transistor connected to a second sensing node and receiving a sensing driving voltage, an output transistor connected between the second sensing node and a read-out line and operating in response to an output control signal, and a control transistor connected between the first sensing node and the sensing capacitor and operating in response to a light receiving control signal. An active period of the output control signal applied to at least one of the sensor circuits may overlaps a non-active period of the light receiving control signal.

The output control signal may be the same signal as the light receiving control signal.

The output transistor and the control transistor may be different types of transistor, and when the output transistor is turned on, the control transistor may be turned off.

The output transistor may be connected to an output control line and receive the output control signal through the output control line, and the control transistor may be connected to a light receiving control line and receive the light receiving control signal through the light receiving control line.

The active period of the output control signal may overlap the non-active period of the light receiving control signal during a first sensing frame and a second sensing frame.

The sensor circuits may accumulate sensing data during the first sensing frame and output the sensing data to the read-out line during the second sensing frame.

The control transistors of the sensor circuits may be commonly connected to a light receiving control line, and the control transistors may commonly receive the light receiving control signal through the light receiving control line.

The display device may include a sensing area and a non-sensing area.

An active period of an output control signal applied to a first sensor circuit disposed in the non-sensing area among the sensor circuits may overlap an active period of a light receiving control signal applied to the first sensor circuit, and an active period of an output control signal applied to a second sensor circuit disposed in the sensing area among the sensor circuits may overlap a non-active period of a light receiving control signal applied to the second sensor circuit.

The sensor circuits may include a first sensor circuit group and a second sensor circuit group, the first sensor circuit group may be connected to a first light receiving control line to receive a first light receiving control signal, and the second sensor circuit group may be connected to a second light receiving control line to receive a second light receiving control signal.

The first light receiving control signal may have a first non-active period, an active period of an output control signal applied to the first sensor circuit group may overlap the first non-active period, the second light receiving control signal may have a second non-active period different from the first non-active period, and an active period of an output control signal applied to the second sensor circuit group may overlap the second non-active period.

The display device may include a first area and a second area, the first sensor circuit group may be disposed in the first area, and the second sensor circuit group may be disposed in the second area.

The pixel circuit may include a driving transistor connected between the light emitting element and a first driving voltage line and a switching transistor connected to the driving transistor and receiving a data voltage and a scan signal.

The scan signal may be the same signal as the output control signal.

The display device may operate during a plurality of display frames, each of the display frames may include a driving section and a blank section, and the scan signal may be sequentially activated during the driving section.

The reset control signal may be activated during the blank section of an i-th display frame, a reset voltage applied through the reset voltage line may be applied to the first sensing node through the reset transistor, and the i is an integer greater than or equal to 1.

According to one or more embodiments, there is provided an electronic device which may include the display device described above and a processor controlling an operation of the display device.

According to one or more embodiments, there is provided a display device which may include a pixel circuit, a sensor circuit, a light emitting element connected to the pixel circuit; and a light receiving element connected the sensor circuit, wherein the sensor circuit includes a sensing capacitor, a reset transistor connected between a reset voltage line and a first sensing node and configured to operate based on a reset control signal, an amplification transistor connected to a second sensing node and configured to receive a sensing driving voltage, an output transistor connected between the second sensing node and a read-out line and configured to operate based on an output control signal, and a control transistor connected between the first sensing node and the sensing capacitor and configured to operate based on a light receiving control signal, wherein the control transistor is configured to be turned off when the output transistor outputs a sensing signal to the read-out line based on the output control signal.

The control transistor may be one of a p-type transistor and an n-type transistor and the output transistor may be the other of the p-type transistor and the n-type transistor.

The control transistor and the output transistor may be configured to receive a common gate input signal.

According to the above, the sensor circuit may include the output transistor that operates in response to the output control signal and the control transistor that operates in response to the light receiving control signal. The sensing data are accumulated according to the amount of light incident to the light receiving element connected to a sensor circuit. During this process, the sensing data may contain noise. According to the disclosure, when the output control signal is activated so that the output transistor outputs the sensing data, the light receiving control signal may be deactivated, thereby preventing accumulation of the sensing data. Consequently, no noise may be included in the sensing data or the sensing data may include reduced noise, and sensing performance of the display device may be improved.

### BRIEF DESCRIPTION OF DRAWINGS

FIG. 1 is a perspective view of an electronic device according to one or more embodiments;

FIG. 2 is a cross-sectional view of a display device according to one or more embodiments;

FIG. 3 is a block diagram of a display device according to one or more embodiments;

FIG. 4A is a circuit diagram of a pixel and a sensor according to one or more embodiments;

FIG. 4B is a waveform diagram illustrating an operation of the pixel and the sensor shown in FIG. 4A;

FIG. 5A is a block diagram of a connection relationship of an output transistor and a control transistor according to one or more embodiments;

FIG. 5B is a timing diagram illustrating an operation of the output transistor and the control transistor shown in FIG. 5A;

FIG. 6 is a circuit diagram of a pixel and a sensor according to one or more embodiments;

FIG. 7A is a block diagram of a connection relationship of an output transistor and a control transistor according to one or more embodiments;

FIG. 7B is a timing diagram illustrating an operation of the output transistor and the control transistor shown in FIG. 7A;

FIG. 8A is a plan view of a display device according to one or more embodiments;

FIG. 8B is a block diagram of a connection relationship of an output transistor and a control transistor according to one or more embodiments;

FIG. 8C is a timing diagram illustrating an operation of the output transistor and the control transistor shown in FIG. 8B;

FIG. 9A is a plan view of a display device according to one or more embodiments;

FIG. 9B is a block diagram of a connection relationship of an output transistor and a control transistor according to one or more embodiments;

FIG. 9C is a timing diagram illustrating an operation of the output transistor and the control transistor shown in FIG. 9B;

FIG. 10 is a block diagram illustrating an electronic device according to one or more embodiments; and

FIG. 11 is a schematic view illustrating various electronic devices according to one or more embodiments.

### DETAILED DESCRIPTION

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature’s relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The embodiments described herein are non-limiting example embodiments, and thus, the disclosure is not limited thereto and may be realized in various other forms. Hereinafter, embodiments of the disclosure will be described with reference to accompanying drawings.

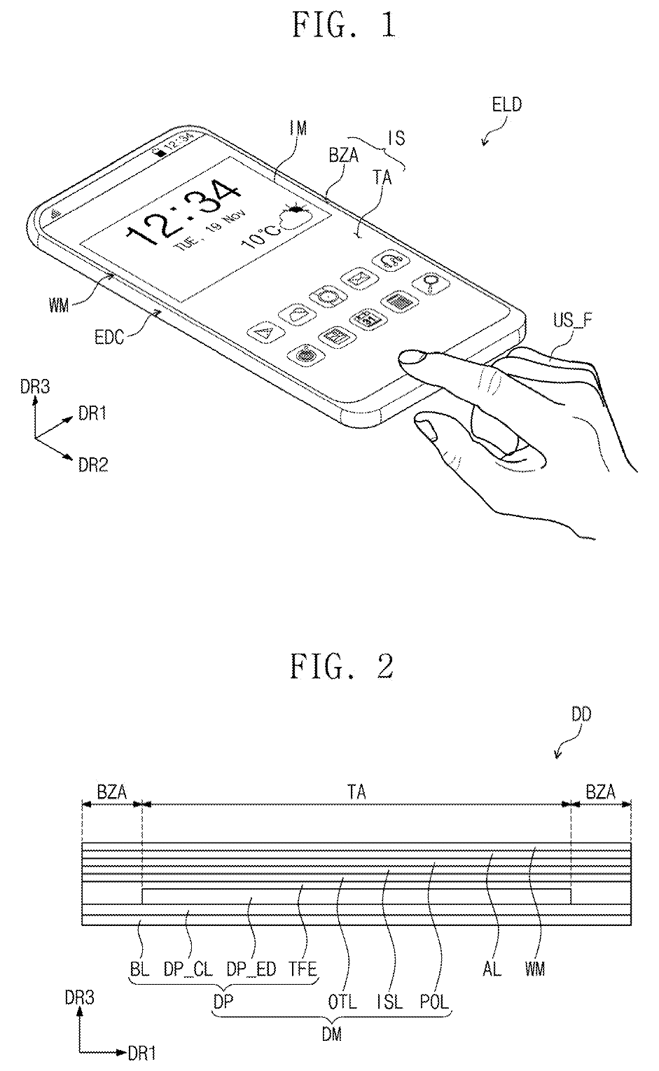

FIG. 1 is a perspective view of an electronic device according to one or more embodiments. FIG. 2 is a cross-sectional view of a display device according to one or more embodiments.

Referring to FIGS. 1 and 2, the electronic device ELD may have a rectangular shape with short sides parallel to a first direction DR1 and long sides parallel to a second direction DR2 intersecting the first direction DR1. However, the shape of the electronic device ELD may not be limited to the rectangular shape, and the electronic device ELD may have different shapes, such as a circular shape, a polygonal shape, or the like.

The electronic device ELD may be activated in response to electrical signals. The electronic device ELD may be implemented in various embodiments. As an example, the electronic device ELD may be applied to electronic devices, such as a smart watch, a tablet computer, a notebook computer, a computer, or a smart television, etc., not being limited thereto.

Hereinafter, a normal line direction substantially perpendicular to a plane defined by the first direction DR1 and the second direction DR2 is referred to as a third direction DR3. In the following descriptions, the expression “in plan view” may mean a state of being viewed in the third direction DR3.

An upper surface of the electronic device ELD may be or include a display surface IS and may be substantially parallel to the plane defined by the first direction DR1 and the second direction DR2. Images IM displayed on the electronic device ELD may be provided to a user through the display surface IS.

The display surface IS may include a transmission area TA and a bezel area BZA. The images IM may be displayed through the transmission area TA. The user may view the images IM through the transmission area TA. In the present embodiment, the transmission area TA may have a quadrangular shape with rounded vertices. However, this is merely an example, and the transmission area TA may have different shapes and may not be particularly limited.

The bezel area BZA may be adjacent to the transmission area TA. The bezel area BZA may have a selected color. The bezel area BZA may surround the transmission area TA. Accordingly, the shape of the transmission area TA may depend on the bezel area BZA, however, this is merely an example. According to an embodiment, the bezel area BZA may be adjacent to only one side of the transmission area TA or may not be present in the display surface IS.

The electronic device ELD may sense an external input applied from an outside. The external input may include a plurality of different external inputs provided from the outside. For example, the external input may include an external input (e.g., a hovering input) detected when in proximity to or approaching close to the electronic device ELD at a selected distance, as well as a touch input from a part of the user’s body, e.g., a finger US_F of the user or from a separate device, e.g., an active pen, a digitizer, or the like. In addition, the external input may take various forms, such as force, pressure, temperature, or light.

The electronic device ELD may sense biometric information of the user, which is applied from the outside. The electronic device ELD may include a biometric information sensing area in the display surface IS to sense the biometric information of the user. The biometric information sensing area may be across an entire portion of the transmission area TA or within a portion of the transmission area TA. FIG. 1 shows a structure in which the entire portion of the transmission area TA is used as the biometric information sensing area.

The electronic device ELD may include a window WM and a housing EDC. In the present embodiment, the window WM and the housing EDC may be coupled to each other to form an exterior of the electronic device ELD. The housing EDC and the window WM coupled to the housing EDC may provide an inner space. The housing EDC may include a material with a relatively high rigidity. For example, the housing EDC may include a glass, plastic, or a metal material or a plurality of frames and/or plates of combinations thereof. The housing EDC may stably protect components of a display device DD (refer to FIG. 2) accommodated in the inner space from external impacts.

A front surface of the window WM may be or include the display surface IS of the electronic device ELD. The window WM may include an optically transparent insulating material. As an example, the window WM may include a glass or plastic material. The window WM may have a single-layer or multi-layer structure. As an example, the window WM may include a plurality of plastic films coupled to each other by an adhesive or a glass substrate and a plastic film coupled to the glass substrate by an adhesive.

Referring to FIG. 2, the display device DD may include a display module DM and the window WM. As an example, the display device DD may be coupled to the housing EDC (refer to FIG. 1) to form the electronic device ELD (refer to FIG. 1). The display module DM may include a display panel DP, an optical layer OTL, an input sensing layer ISL, and a polarizing layer POL. The display panel DP may display images in response to electrical signals, and the input sensing layer ISL may sense external inputs applied from the outside. The external inputs may be provided in various forms.

The display panel DP according to the disclosure may be a light-emitting type display panel, however, it may not be particularly limited thereto. For instance, the display panel DP may be an organic light emitting display panel, an inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. A light emitting layer of the quantum dot light emitting display panel may include a quantum dot or a quantum rod. Hereinafter, the organic light emitting display panel will be described as an example of the display panel DP.

The display panel DP may include a base layer BL, a circuit layer DP_CL, an element layer DP_ED, and an encapsulation layer TFE. The display panel DP may be a flexible display panel, however, the disclosure may not be limited thereto or thereby. As an example, the display panel DP may be a foldable display panel folded with respect to a folding axis or a rigid display panel.

The base layer BL may include a synthetic resin layer. The synthetic resin layer may be a polyimide-based resin layer, however, a material for the synthetic resin layer may not be limited thereto. In addition, the base layer BL may include a glass substrate, a metal substrate, or an organic/inorganic composite material substrate.

The circuit layer DP_CL may be disposed on the base layer BL. The circuit layer DP_CL may be disposed between the base layer BL and the element layer DP_ED. The circuit layer DP_CL may include at least one insulating layer and a circuit element. Hereinafter, the insulating layer included in the circuit layer DP_CL is referred to as an intermediate insulating layer. The intermediate insulating layer may include at least one intermediate inorganic layer and at least one intermediate organic layer. The circuit element may include a pixel circuit included in each of pixels displaying images and a sensor circuit included in each of sensors recognizing external information. The external information may be the biometric information. As an example, the sensor may be a fingerprint recognition sensor, a proximity sensor, an iris recognition sensor, a blood pressure measurement sensor, an illumination sensor, or the like. In addition, the sensor may be an optical sensor that recognizes the biometric information in an optical manner. The circuit layer DP_CL may further include signal lines connected to the pixel circuit and/or the sensor circuit.

The element layer DP_ED may include a light emitting element included in each of the pixels and a light receiving element included in each of the sensors. As an example, the light receiving element may be a photodiode. The light receiving element may be a sensor that senses a light reflected by a user’s fingerprint or responds to the light.

The encapsulation layer TFE may encapsulate the element layer DP_ED. The encapsulation layer TFE may include at least one organic layer and at least one inorganic layer. The inorganic layer may include an inorganic material and may protect the element layer DP_ED from moisture and oxygen. The inorganic layer may include a silicon nitride layer, a silicon oxynitride layer, a silicon oxide layer, a titanium oxide layer, or an aluminum oxide layer, however, it may not be limited thereto or thereby. The organic layer may include an organic material and may protect the element layer DP_ED from a foreign substance such as dust particles.

The optical layer OTL may be disposed on the display panel DP. The optical layer OTL may form an optical system to transmit light to the light receiving element. According to an embodiment, the optical layer OTL may be formed on the display panel DP through a continuous process. For example, when the optical layer OTL is disposed directly on the encapsulation layer TFE of the display panel DP, a separate adhesive film may not be disposed between the optical layer OTL and the encapsulation layer TFE.

The input sensing layer ISL may be disposed on the optical layer OTL. The input sensing layer ISL may be disposed directly on the optical layer OTL. The input sensing layer ISL may be formed on the optical layer OTL through a continuous process. For example, when the input sensing layer ISL is disposed directly on the optical layer OTL, an adhesive member may not be disposed between the input sensing layer ISL and the optical layer OTL. Alternatively, an adhesive film may be disposed between the input sensing layer ISL and the optical layer OTL. In this case, the input sensing layer ISL may be fixed onto an upper surface of the display panel DP by the adhesive film after being formed separately from the display panel DP and the optical layer OTL.

The input sensing layer ISL may sense the external input, e.g., a user’s touch, may convert the external input to an input signal, and may apply the input signal to the display panel DP. The input sensing layer ISL may include a plurality of sensing electrodes to sense the external input. The sensing electrodes may sense the external input by a capacitance method. The display panel DP may receive an input signal from the input sensing layer ISL and may generate an image corresponding to the input signal.

The position of the optical layer OTL should not be limited to that shown in FIG. 2. As an example, the optical layer OTL may be disposed on the input sensing layer ISL. In this case, the input sensing layer ISL may be disposed directly on the encapsulation layer TFE, and the optical layer OTL may be disposed directly on the input sensing layer ISL.

The display module DM may further include a polarizing layer POL. As an example, the polarizing layer POL may be disposed on the input sensing layer ISL, however, the disclosure may not be limited thereto or thereby. When the optical layer OTL is disposed on the input sensing layer ISL, the polarizing layer POL may be disposed on the optical layer OTL. The optical layer OTL may include a black matrix including one or more transmissive holes.

The polarizing layer POL may include a transmission axis and an absorption axis perpendicular to the transmission axis. Accordingly, the polarizing layer POL may transmit light components that vibrate in a direction parallel to the transmission axis and may absorb light components that vibrate in a direction parallel to the absorption axis. As an example, the transmission axis and the absorption axis of the polarizing layer POL may be inclined with respect to the first and second directions DR1 and DR2. As an example, the transmission axis may be parallel to a diagonal direction inclined at an angle of about 45° with respect to the first direction DR1, and the absorption axis may be parallel to a diagonal direction inclined at an angle of about 45° with respect to the second direction DR2.

The display device DD may further include an adhesive layer AL. The window WM may be attached to the polarizing layer POL by the adhesive layer AL. The adhesive layer AL may include an optically clear adhesive (OCA), an optically clear adhesive resin (OCR), or a pressure sensitive adhesive (PSA).

A battery module may be disposed between the display module DM and the housing EDC to supply a power source required for an overall operation of the display device DD.

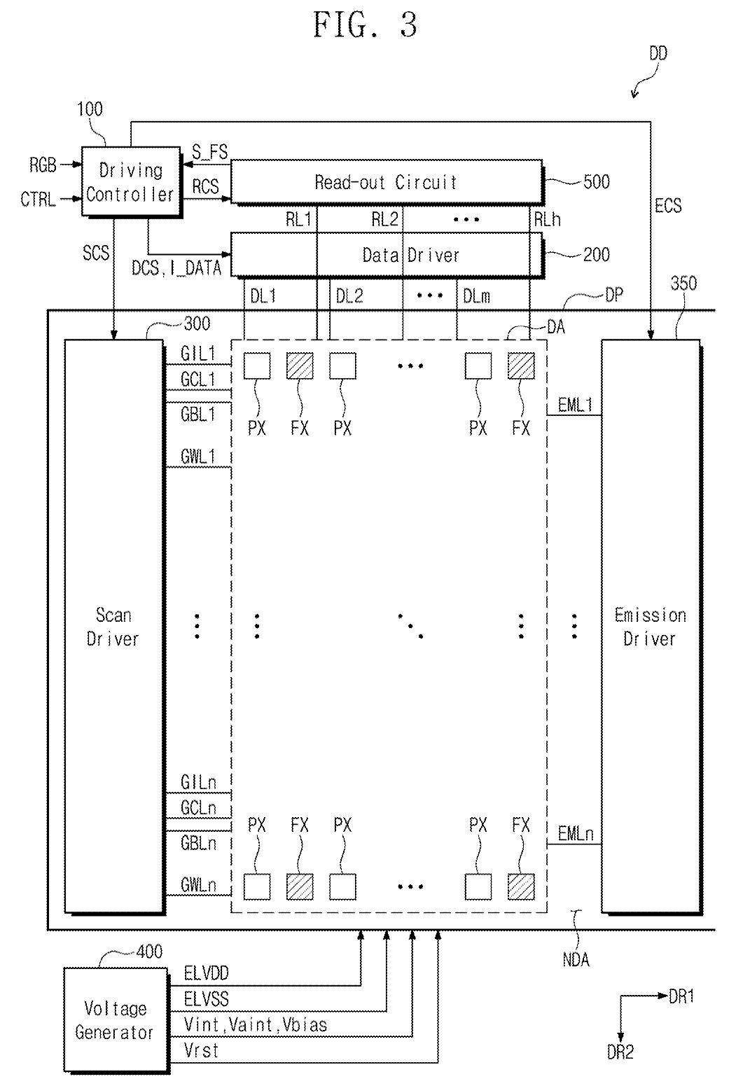

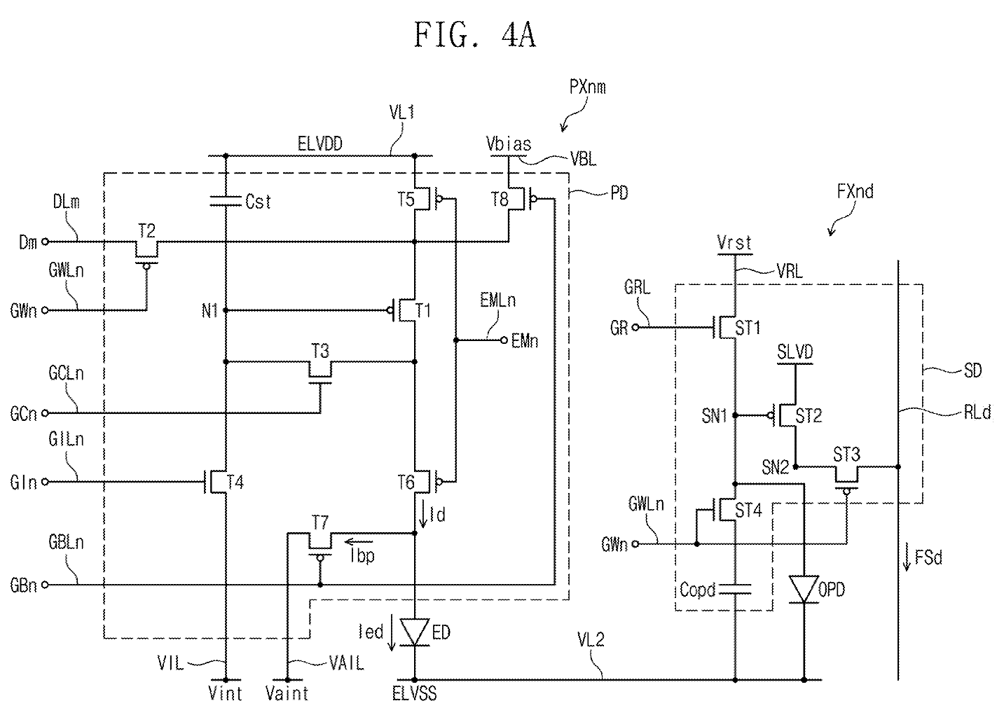

FIG. 3 is a block diagram of the display device DD of FIG. 2 according to one or more embodiments.

Referring to FIG. 3, the display device DD may include the display panel DP, a panel driver, and a driving controller 100. As an example, the panel driver may include a data driver 200, a scan driver 300, an emission driver 350, a voltage generator 400, and a read-out circuit 500.

The driving controller 100 may receive an image signal RGB and control signals CTRL. The driving controller 100 may convert a data format of the image signal RGB to a data format appropriate to an interface between the data driver 200 and the driving controller 100 to generate image data I_DATA. The driving controller 100 may generate a first control signal SCS, a second control signal ECS, a third control signal DCS, and a fourth control signal RCS.

The data driver 200 may receive the third control signal DCS and the image data I_DATA from the driving controller 100. The data driver 200 may convert the image data I_DATA to data signals and may output the data signals to a plurality of data lines DL1 to DLm to be described later. The data signals may be analog voltages corresponding to grayscale values of the image data I_DATA.

The scan driver 300 may receive the first control signal SCS from the driving controller 100. The scan driver 300 may output scan signals to scan lines in response to the first control signal SCS.

The voltage generator 400 may generate voltages required to operate the display panel DP. In the present embodiment, the voltage generator 400 may generate a first driving voltage ELVDD, a second driving voltage ELVSS, a first initialization voltage VINT1, a second initialization voltage VINT2, a bias voltage Vbias, and a reset voltage Vrst.

The display panel DP may include a display area DA corresponding to the transmission area TA (refer to FIG. 1) and a non-display area NDA corresponding to the bezel area BZA (refer to FIG. 1).

The display panel DP may include a plurality of pixels PX disposed in the display area DA and a plurality of sensors FX disposed in the display area DA. As an example, each of the sensors FX may be disposed between two pixels PX adjacent to each other. The pixels PX and the sensors FX may be alternately arranged with each other in the first and second directions DR1 and DR2, however, the disclosure may not be limited thereto or thereby. For example, two or more pixels PX may be disposed between two sensors FX adjacent to each other in the first direction DR1 among the sensors FX, or two or more pixels PX may be disposed between two sensors FX adjacent to each other in the second direction DR2 among the sensors FX.

The display panel DP may further include initialization scan lines GIL1 to GILn, compensation scan lines GCL1 to GCLn, write scan lines GWL1 to GWLn, black scan lines GBL1 to GBLn, emission control lines EML1 to EMLn, the data lines DL1 and DL2 to DLm, and read-out lines RL1 and RL2 to RLh. The initialization scan lines GIL1 to GILn, the compensation scan lines GCL1 to GCLn, the write scan lines GWL1 to GWLn, the black scan lines GBL1 to GBLn, and the emission control lines EML1 to EMLn may extend in the first direction DR1 and may be spaced apart from each other while being arranged in the second direction DR2. The data lines DL1 to DLm and the read-out lines RL1 to RLh may extend in the second direction DR2 and may be spaced apart from each other in the first direction DR1 while being arranged in the first direction DR1. In the present embodiment, each of n, m, and d may be a natural number greater than or equal to 1.

The pixels PX may be electrically connected to the initialization scan lines GIL1 to GILn, the compensation scan lines GCL1 to GCLn, the write scan lines GWL1 to GWLn, the black scan lines GBL1 to GBLn, the emission control lines EML1 to EMLn, and the data lines DL1 to DLm. As an example, each of the pixels PX may be electrically connected to four scan lines. However, the number of the scan lines connected to each of the pixels PX may not be limited thereto.

The sensors FX may be electrically connected to the write scan lines GWL1 to GWLn and the read-out lines RL1 to RLh. Each of the sensors FX may be electrically connected to one scan line, however, the disclosure may not be limited thereto or thereby. The number of the scan lines connected to each of the sensors FX may vary. As an example, the number of the read-out lines RL1 to RLh may be smaller than or equal to the number of the data lines DL1 to DLm. As an example, the number of the read-out lines RL1 to RLh may correspond to a 1/2, 1/4, or 1/8 of the number of the data lines DL1 to DLm.

The scan driver 300 may be disposed in the non-display area NDA of the display panel DP. The scan driver 300 may receive the first control signal SCS from the driving controller 100. Responsive to the first control signal SCS, the scan driver 300 may output initialization scan signals to the initialization scan lines GIL1 to GILn and may output compensation scan signals to the compensation scan lines GCL1 to GCLn. In addition, responsive to the first control signal SCS, the scan driver 300 may output write scan signals to the write scan lines GWL1 to GWLn and may output black scan signals to the black scan lines GBL1 to GBLn. Alternatively, the scan driver 300 may include first and second scan drivers. The first scan driver may output the initialization scan signals and the compensation scan signals, and the second scan driver may output the write scan signals and the black scan signals.

The emission driver 350 may be disposed in the non-display area NDA of the display panel DP. The emission driver 350 may receive the second control signal ECS from the driving controller 100. The emission driver 350 may output light emission control signals to the emission control lines EML1 to EMLn in response to the second control signal ECS. According to an embodiment, alternatively, the scan driver 300 may be connected to the emission control lines EML1 to EMLn. In this case, the emission driver 350 may be omitted or removed from the display device DD, and the scan driver 300 may output the light emission control signals to the emission control lines EML1 to EMLn.

The read-out circuit 500 may receive the fourth control signal RCS from the driving controller 100. The read-out circuit 500 may receive sensing signals from the read-out lines RL1 to RLh in response to the fourth control signal RCS. The read-out circuit 500 may process the sensing signals from the read-out lines RL1 to RLh and may provide the processed sensing signals S_FS to the driving controller 100. The driving controller 100 may recognize the biometric information based on the sensing signals S_FS.

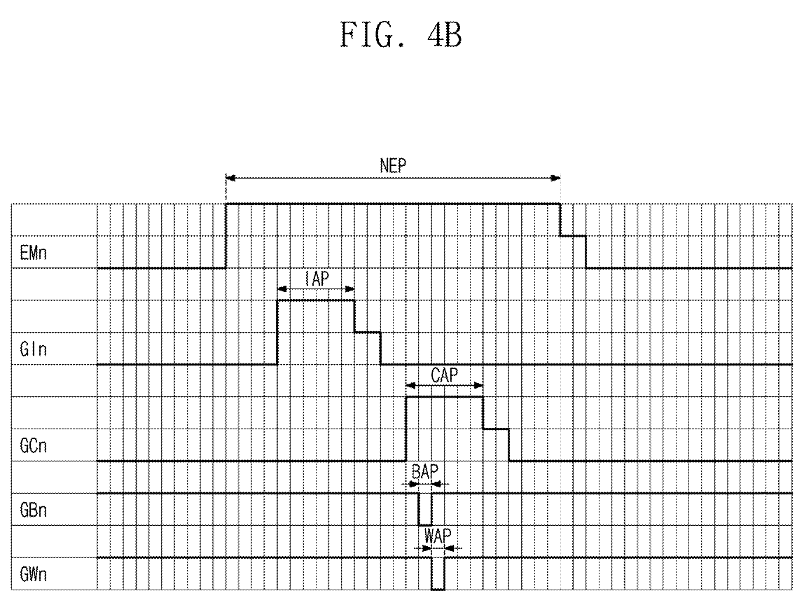

FIG. 4A is a circuit diagram of the pixel PX and the sensor FX of the display panel DP of FIG. 3 according to one or more embodiments, and FIG. 4B is a waveform diagram illustrating an operation of the pixel PX and the sensor FX shown in FIG. 4A.

FIG. 4A shows an equivalent circuit diagram of one pixel PXnm among the pixels PX shown in FIG. 3. Since the pixels PX have substantially the same circuit configuration, the circuit configuration of one pixel PXnm will be described in detail, and descriptions of the other pixels will be omitted. In addition, FIG. 4A shows an equivalent circuit diagram of one sensor FXnd of the sensors FX shown in FIG. 3. Since the sensors FX have substantially the same circuit configuration, the circuit configuration of one sensor FXnd will be described in detail, and descriptions of the other sensors will be omitted.

Referring to FIG. 4A, the pixel PXnm may be connected to an m-th data line DLm among the data lines DL1 to DLm, an n-th initialization scan line GILn among the initialization scan lines GIL1 to GILn, an n-th compensation scan line GCLn among the compensation scan lines GCL1 to GCLn, an n-th write scan line GWLn among the write scan lines GWL1 to GWLn, an n-th black scan line GBLn among the black scan lines GBL1 to GBLn, and an n-th emission control line EMLn among the emission control lines EML1 to EMLn.

The pixel PXnm may include a light emitting element ED and a pixel circuit PD. The light emitting element ED may be a light emitting diode. As an example, the light emitting element ED may be an organic light emitting diode including an organic light emitting layer.

The pixel circuit PD may include first, second, third, fourth, fifth, sixth, seventh, and eighth transistors T1, T2, T3, T4, T5, T6, T7, and T8 and one capacitor Cst. At least one of the first to eighth transistors T1 to T8 may each be a transistor including a low-temperature polycrystalline silicon (LTPS) semiconductor layer. Some transistors of the first to eighth transistors T1 to T8 may each be a P-type transistor, and the other transistors may each be an N-type transistor. At least one of the first to eighth transistors T1 to T8 may be a transistor including an oxide semiconductor layer. As an example, the third and fourth transistors T3 and T4 may each be an oxide semiconductor transistor, and the first, second, and fifth to eighth transistors T1, T2, and T5 to T8 may each be an LTPS transistor. The third and fourth transistors T3 and T4 may each be an N-type transistor.

The circuit configuration of the pixel circuit PD according to the disclosure should not be limited to the embodiment shown in FIG. 4A. The pixel circuit PD shown in FIG. 4A is merely an example, and the circuit configuration of the pixel circuit PD may be changed. As an example, all of the first, second, and fifth to eighth transistors T1, T2, and T5 to T8 may be a P-type transistor or an N-type transistor.

The n-th initialization scan line GILn, the n-th compensation scan line GCLn, the n-th write scan line GWLn, the n-th black scan line GBLn, and the n-th emission control line EMLn may transmit an n-th initialization scan signal GIn, an n-th compensation scan signal GCn, an n-th write scan signal GWn, an n-th black scan signal GBn, and an n-th emission control signal EMn to the pixel PXnm, respectively. The m-th data line DLm may transmit an m-th data signal Dm to the pixel PXnm. The m-th data signal Dm may have a voltage level corresponding to the image signal RGB (refer to FIG. 3) input to the display device DD (refer to FIG. 3).

As an example, the pixel PXnm may be connected to first and second driving voltage lines VL1 and VL2, first and second initialization voltage lines VIL and VAIL, and a bias voltage line VBL. The first driving voltage line VL1 may transmit the first driving voltage ELVDD to the pixel PXnm, and the second driving voltage line VL2 may transmit the second driving voltage ELVSS to the pixel PXnm. In addition, the first initialization voltage line VIL may transmit the first initialization voltage Vint to the pixel PXnm, and the second initialization voltage line VAIL may transmit a second initialization voltage Vaint to the pixel PXnm. The bias voltage line VBL may transmit the bias voltage Vbias to the pixel PXnm.

The first transistor T1 may be connected between the first driving voltage line VL1 to which the first driving voltage ELVDD is applied and the light emitting element ED. The first transistor T1 may be referred to as a driving transistor. The first transistor T1 may include a first electrode connected to the first driving voltage line VL1 through the fifth transistor T5, a second electrode connected to an anode electrode of the light emitting element ED through the sixth transistor T6, and a third electrode, e.g., a gate electrode, connected to one end, e.g., a first node N1, of the capacitor Cst. The first transistor T1 may receive the m-th data signal Dm via the m-th data line DLm according to a switching operation of the second transistor T2 and may supply a driving current Id to the light emitting element ED.

The second transistor T2 may be connected between the data line DLm and the first electrode of the first transistor T1. The second transistor T2 may be referred to as a switching transistor. The second transistor T2 may include a first electrode connected to the data line DLm, a second electrode connected to the first electrode of the first transistor T1, and a third electrode, e.g., a gate electrode, connected to the n-th write scan line GWLn. The second transistor T2 may be turned on in response to the write scan signal GWn applied through the n-th write scan line GWLn and may transmit the m-th data signal Dm provided from the m-th data line DLm to the first electrode of the first transistor T1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode, e.g., a gate electrode, connected to the n-th compensation scan line GCLn. The third transistor T3 may be turned on in response to the n-th compensation scan signal GCn applied through the n-th compensation scan line GCLn and may connect the second electrode and the third electrode of the first transistor T1, and thus, the first transistor T1 may be connected in a diode configuration.

The fourth transistor T4 may be connected between the first initialization voltage line VIL to which the first initialization voltage Vint is applied and the first node N1. The fourth transistor T4 may include a first electrode connected to the first initialization voltage line VIL to which the first initialization voltage Vint is applied, a second electrode connected to the first node N1, and a third electrode, e.g., a gate electrode, connected to the n-th initialization scan line GILn. The fourth transistor T4 may be turned on in response to the n-th initialization scan signal GIn applied through the n-th initialization scan line GILn. The turned-on fourth transistor T4 may supply the first initialization voltage Vint to the first node N1 to initialize an electric potential of the third electrode of the first transistor T1, e.g., an electric potential of the first node N1.

The fifth transistor T5 may include a first electrode connected to the first driving voltage line VL1, a second electrode connected to the first electrode of the first transistor T1, and a third electrode, e.g., a gate electrode, connected to the n-th emission control line EMLn.

The sixth transistor T6 may include a first electrode connected to the second electrode of the first transistor T1, a second electrode connected to the anode electrode of the light emitting element ED, and a third electrode, e.g., a gate electrode, connected to the n-th emission control line EMLn.

The fifth and sixth transistors T5 and T6 may be substantially simultaneously turned on in response to the n-th emission control signal EMn applied through the n-th emission control line EMLn. The first driving voltage ELVDD provided through the turned-on fifth transistor T5 may be compensated for through the diode-connected first transistor T1 and then may be supplied to the light emitting element ED.

The seventh transistor T7 may include a first electrode connected to the second initialization voltage line VAIL to which the second initialization voltage Vaint is applied, a second electrode connected to the second electrode of the sixth transistor T6, and a third electrode, e.g., a gate electrode, connected to the n-th black scan line GBLn. The second initialization voltage Vaint may have a voltage level lower than or equal to that of the first initialization voltage Vint.

The eighth transistor T8 may include a first electrode connected to the bias voltage line VBL to which the bias voltage Vbias is applied, a second electrode connected to the first electrode of the first transistor T1, and a third electrode, e.g., a gate electrode, connected to the n-th black scan line GBLn.

The seventh and eighth transistors T7 and T8 may be substantially simultaneously turned on in response to the n-th black scan signal GBn received through the n-th black scan line GBLn. The second initialization voltage Vaint applied through the turned-on seventh transistor T7 may be applied to the anode electrode of the light emitting element ED. Accordingly, the anode electrode of the light emitting element ED may be initialized to the second initialization voltage Vaint. In addition, the bias voltage Vbias applied through the turned-on eighth transistor T8 may be applied to the first electrode of the first transistor T1. Thus, the bias voltage Vbias may be periodically applied to the first electrode of the first transistor T1, and as a result, degradation in display quality, which is caused by an increase, due to hysteresis, in the potential difference between the first and second electrodes of the first transistor T1 beyond a certain level, may be prevented.

As described above, the one end of the capacitor Cst may be connected to the third electrode of the first transistor T1, and the other end of the capacitor Cst may be connected to the first driving voltage line VL1. A cathode electrode of the light emitting element ED may be connected to the second driving voltage line VL2 transmitting the second driving voltage ELVSS. The second driving voltage ELVSS may have a voltage level lower than that of the first driving voltage ELVDD. As an example, the second driving voltage ELVSS may have a voltage level lower than that of the first and second initialization voltages Vint and Vaint.

Referring to FIGS. 4A and 4B, the n-th emission control signal EMn may have a high level during a non-emission period NEP. The n-th initialization scan signal GIn may be activated within the non-emission period NEP. When the n-th initialization scan signal GIn having the high level is provided through the n-th initialization scan line GILn during an activation period IAP (hereinafter, referred to as an initialization activation period) of the n-th initialization scan signal GIn, the fourth transistor T4 may be turned on in response to the n-th initialization scan signal GIn having the high level. The first initialization voltage Vint may be applied to the third electrode of the first transistor T1 through the turned-on fourth

transistor T4, and the first node N1 may be initialized to the first initialization voltage Vint. Accordingly, the initialization activation period IAP may be or correspond to an initialization period of the pixel PXnm.

Then, when the n-th compensation scan signal GCn is activated and the n-th compensation scan signal GCn having the high level is provided through the n-th compensation scan line GCLn during an activation period CAP (hereinafter, referred to as a compensation activation period) of the n-th compensation scan signal GCn, the third transistor T3 may be turned on. The first transistor T1 may be connected in a diode configuration by the turned-on third transistor T3 and may be forward biased. The initialization activation period IAP may not overlap the compensation activation period CAP.

The n-th write scan signal GWn may be activated within the compensation activation period CAP. The n-th write scan signal GWn may have a low level during an activation period WAP (hereinafter, referred to as a write activation period). The second transistor T2 may be turned on in response to the n-th write scan signal GWn having the low level during the write activation period WAP. Then, a compensation voltage “Dm-Vth”, which is reduced by a threshold voltage Vth of the first transistor T1 from the m-th data signal Dm provided through the m-th data line DLm, may be applied to the third electrode of the first transistor T1. For example, an electric potential of the third electrode of the first transistor T1 may be the compensation voltage “Dm-Vth”. The write activation period WAP may overlap the compensation activation period CAP. A duration of the compensation activation period CAP may be longer than a duration of the write activation period WAP.

The first driving voltage ELVDD and the compensation voltage “Dm-Vth” may be respectively applied to opposite ends of the capacitor Cst, and the capacitor Cst may be charged with electric charges corresponding to a difference in voltage between the opposite ends of the capacitor Cst. A high level period of the n-th compensation scan signal GCn may be referred to as a compensation period of the pixel PXnm.

The n-th black scan signal GBn may be activated within the compensation activation period CAP of the n-th compensation scan signal GCn. The n-th black scan signal GBn may have the low level during an activation period BAP (hereinafter, referred to as a black activation period). During the black activation period BAP, the seventh transistor T7 may be turned on in response to the n-th black scan signal GBn having the low level applied through the n-th black scan line GBLn. A portion of the driving current Id may be bypassed as a bypass current Ibp via the seventh transistor T7. The black activation period BAP may overlap the compensation activation period CAP. The duration of the compensation activation period CAP may be longer than a duration of the black activation period BAP. The black activation period BAP may precede the write activation period WAP and may not overlap the write activation period WAP.

In a case where the pixel PXnm displays a black image, if the light emitting element ED emits light even when a minimum driving current of the first transistor T1 flows as the driving current Id, the pixel PXnm may not properly display the black image. Therefore, in the pixel PXnm according to one or more embodiments, the seventh transistor T7 may divert a part of the minimum driving current of the first transistor T1 as the bypass current Ibp along a path different from the current path to the light emitting element ED. In this case, the minimum driving current of the first transistor T1 may refer to a current flowing through the first transistor T1 under a condition that a gate-source voltage Vgs of the first transistor T1 is lower than the threshold voltage Vth and the first transistor T1 is turned off. The minimum driving current flowing through the first transistor T1 under the condition that the first transistor T1 is turned off, for example, a current of less than about 10 pA, is transmitted to the light emitting element ED, and an image with a black grayscale may be displayed. In the case where the pixel PXnm displays the black image, an influence of the bypass current Ibp on the minimum driving current is relatively large, however, in the case where images, such as a normal image or a white image, are displayed, the influence of the bypass current Ibp on the driving current Id may be considered negligible. Accordingly, when the black image is displayed, a current,e.g., a light emitting current Ied, which is reduced by an amount of the bypass current Ibp flowing out from the driving current Id through the seventh transistor T7, may be provided to the light emitting element ED, enabling a more accurate representation of the black image. Thus, the pixel PXnm may display an accurate black grayscale image utilizing the seventh transistor T7, and as a result, a contrast ratio may be improved.

Then, a level of the n-th emission control signal EMn provided from the n-th emission control line EMLn may be changed to the low level from the high level. The fifth and sixth transistors T5 and T6 may be turned on in response to the n-th emission control signal EMn having the low level. As a result, the driving current Id may be generated due to a difference in voltage between the voltage of the third electrode of the first transistor T1 and the first driving voltage ELVDD, the driving current Id may be supplied to the light emitting element ED via the sixth transistor T6, and thus, the light emitting current Ied may flow through the light emitting element ED.

Referring to FIG. 4A again, the sensor FXnd may be connected to a d-th read-out line RLd among the read-out lines RL1 to RLh, the n-th write scan line GWLn, and a reset control line GRL.

The sensor FXnd may include a light receiving element OPD and a sensor circuit SD. As an example, the light receiving element OPD may be an organic photodiode including an organic material as a photoelectric conversion layer. FIG. 4A shows a structure in which the sensor FXnd includes one light sensing element as an example, however, the disclosure may not be limited thereto or thereby. As an example, the sensor FXnd may include multiple light sensing elements OPD connected to each other in parallel.

An anode electrode of the light receiving element OPD may be connected to a first sensing node SN1, and a cathode electrode of the light receiving element OPD may be connected to the second driving voltage line VL2 transmitting the second driving voltage ELVSS. The cathode electrode of the light receiving element OPD may be electrically connected to the cathode electrode of the light emitting element ED. As an example, the cathode electrode of the light receiving element OPD may be formed integrally with the cathode electrode of the light emitting element ED to form a common cathode electrode.

The sensor circuit SD may include four transistors ST1, ST2, ST3, and ST4 and a sensing capacitor Copd. The four transistors ST1, ST2, ST3, and ST4 may be a reset transistor ST1, an amplification transistor ST2, an output transistor ST3, and a control transistor ST4, respectively. At least one of the reset transistor ST1, the amplification transistor ST2, the output transistor ST3, and the control transistor ST4 may be an oxide semiconductor transistor. As an example, the reset transistor ST1 and the control transistor ST4 may be the oxide semiconductor transistor, and the amplification transistor ST2 and the output transistor ST3 may be the LTPS transistor, however, the disclosure may not be limited thereto or thereby. According to one or more embodiments, at least the reset transistor ST1 and the output transistor ST3 may be the oxide semiconductor transistor, and the amplification transistor ST2 and the control transistor ST4 may be the LTPS transistor.

In addition, some of the reset transistor ST1, the amplification transistor ST2, the output transistor ST3, and the control transistor ST4 may be a P-type transistor, and the other transistors may be an N-type transistor. As an example, the amplification transistor ST2 and the output transistor ST3 may each be a PMOS transistor, and the reset transistor ST1 and the control transistor ST4 may each be an NMOS transistor, however, the disclosure may not be limited thereto or thereby. According to one or more embodiments, the reset transistor ST1, the amplification transistor ST2, the output transistor ST3, and the control transistor ST4 may all be an N-type transistor or a P-type transistor.

One or more transistors, for example, the reset transistor ST1 and the control transistor ST4, among the reset transistor ST1, the amplification transistor ST2, the output transistor ST3, and the control transistor ST4 may be the same type of transistor as the third and fourth transistors T3 and T4 of the pixel PXnm. The amplification transistor ST2 and the output transistor ST3 may be the same type of transistor as the first, second, and fifth to eighth transistors T1, T2, and T5 to T8 of the pixel PXnm. As an example, the output transistor ST3 and the control transistor ST4 may be different types of transistors. For example, the output transistor ST3 may be a P-type transistor, and the control transistor ST4 may be an N-type transistor. Accordingly, even when the output transistor ST3 and the control transistor ST4 receive a same signal, turn-on timings of the output transistor ST3 and the control transistor ST4 may differ from each other.

The circuit configuration of the sensor circuit SD may not be limited to that shown in FIG. 4A. The sensor circuit SD shown in FIG. 4A is merely an example, and the circuit configuration of the sensor circuit SD may be modified in various ways.

The reset transistor ST1 may include a first electrode receiving the reset voltage Vrst, a second electrode connected to the first sensing node SN1, and a third electrode receiving a reset control signal GR. The reset transistor ST1 may reset an electric potential of the first sensing node SN1 to the reset voltage Vrst in response to the reset control signal GR. The reset control signal GR may be a signal provided through the reset control line GRL. As an example, the reset voltage Vrst may have a voltage level lower than that of the second driving voltage ELVSS at least during an activation period of the reset control signal GR. The reset voltage Vrst may be transmitted to the sensor FXnd via the reset voltage line VRL. The reset voltage Vrst may be a DC voltage maintained at a voltage level lower than that of the second driving voltage ELVSS.

The amplification transistor ST2 may include a first electrode receiving a sensing driving voltage SLVD, a second electrode connected to a second sensing node SN2, and a third electrode connected to the first sensing node SN1. The amplification transistor ST2 may be turned on depending on the electric potential of the first sensing node SN1 and may apply the sensing driving voltage SLVD to the second sensing node SN2. As an example, the sensing driving voltage SLVD may be one of the first driving voltage ELVDD and the first and second initialization voltages Vint and Vaint. When the sensing driving voltage SLVD is the first driving voltage ELVDD, the first electrode of the amplification transistor ST2 may be electrically connected to the first driving voltage line VL1. When the sensing driving voltage SLVD is the first initialization voltage Vint, the first electrode of the amplification transistor ST2 may be electrically connected to the first initialization voltage line VIL, and when the sensing driving voltage SLVD is the second initialization voltage Vaint, the first electrode of the amplification transistor ST2 may be electrically connected to the second initialization voltage line VAIL. The amplification transistor ST2 may be a source follower amplifier that generates a source-drain current in proportion to the electric potential of the first sensing node SN1 input to the third electrode.

The output transistor ST3 may include a first electrode connected to the second sensing node SN2, a second electrode connected to the d-th read-out line RLd, and a third electrode receiving an output control signal. The output transistor ST3 may apply a sensing signal FSd to the d-th read-out line RLd in response to the output control signal. The output control signal may be the n-th write scan signal GWn provided through the n-th write scan line GWLn.

The control transistor ST4 may include a first electrode connected to the sensing capacitor Copd, a second electrode connected to the first sensing node SN1, and a third electrode receiving a light receiving control signal. The light receiving control signal may be the n-th write scan signal GWn provided through the n-th write scan line GWLn.

As an example, the output control signal and the light receiving control signal may be a same signal. For example, the output transistor ST3 may receive the n-th write scan signal GWn provided from the write scan line GWLn as the output control signal, and the control transistor ST4 may receive the n-th write scan signal GWn provided from the write scan line GWLn as the light receiving control signal. Since the output transistor ST3 and the control transistor ST4 are different types of transistor, even when the output transistor ST3 and the control transistor ST4 receive a same signal respectively as the output control signal and the light receiving control signal, the turn-on periods of the output transistor ST3 and the control transistor ST4 may differ from each other.

In an embodiment of the disclosure, the output control signal and the light receiving control signal may be different signals from each other.

When the reset control signal GR having the high level is applied through the reset control line GRL during a reset period, the reset transistor ST1 is turned on. The reset period may be an activation period, e.g., a high level period, in which the reset control signal GR is activated. Alternatively, when the reset transistor ST1 is implemented as a P-type transistor, the reset control signal GR having the low level may be applied through the reset control line GRL during the reset period. During the reset period, the first sensing node SN1 may be reset (or initialized) to the electric potential corresponding to the reset voltage Vrst. As an example, the reset voltage Vrst may have a voltage level lower than that of the second driving voltage ELVSS.

The light receiving element OPD of the sensor FXnd may be exposed to light during a light emission period of the light emitting element ED. The light may be the light emitted from the light emitting element ED.

When a user’s finger US_F (refer to FIG. 1) touches the display surface IS (refer to FIG. 1), the light receiving element OPD may generate photo-charges corresponding to the light reflected by ridges of the user’s fingerprint or valleys between the ridges of the user’s fingerprint. The amount of current flowing through light receiving element OPD may vary depending on the generated photo-charges. When the light receiving element OPD receives the light reflected by the ridges of the user’s fingerprint, the current flowing through the light receiving element OPD may be referred to as a first current, and when the light receiving element OPD receives the light reflected by the valleys of the user’s fingerprint, the current flowing through the light receiving element OPD may be referred to as a second current. Since the amount of the light reflected by the ridges of the user’s fingerprint and the amount of the light reflected by the valleys of the user’s fingerprint are different from each other, this difference in light amount is represented as the difference between the first and second currents. When the first current flows through the light receiving element OPD, an electric potential of the first sensing node SN1 may be referred to as a first electric potential, and when the second current flows through the light receiving element OPD, the electric potential of the first sensing node SN1 may be referred to as a second electric potential. As an example, the first current may be greater than the second current, and in this case, the first electric potential may be lower than the second electric potential.

During the write activation period WAP, the n-th write scan signal GWn having the low level may be applied to the output transistor ST3 via the n-th write scan line GWLn. When the output transistor ST3 is turned on in response to the n-th write scan signal GWn having the low level, the sensing signal FSd corresponding to a current flowing through the amplification transistor ST2 may be output to the d-th read-out line RLd.

During a period other than the write activation period WAP, the control transistor ST4 may be turned on in response to the n-th write scan signal GWn having the high level. The sensing capacitor Copd may be connected to the first sensing node SN1 through the turned-on control transistor ST4. Accordingly, the charges stored in the sensing capacitor Copd may be discharged in correspondence with the current flowing through the light receiving element OPD, and thus, the electric potential of the first sensing node SN1 may vary.

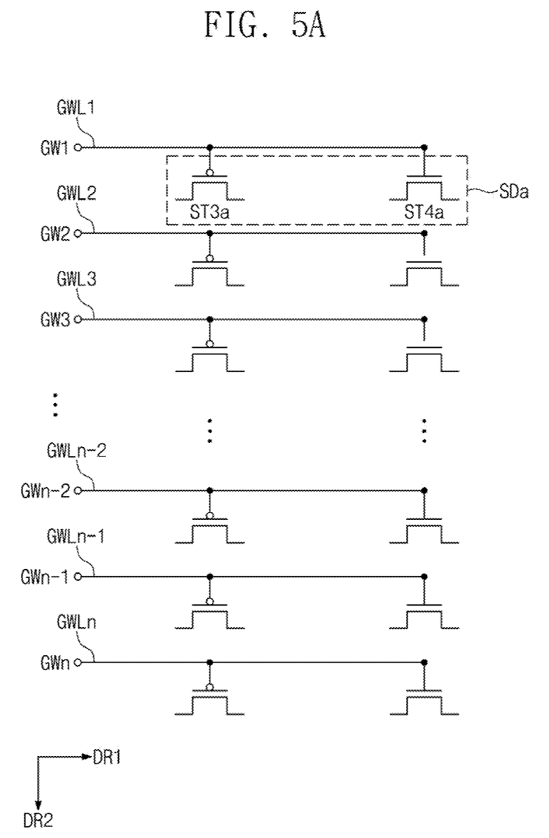

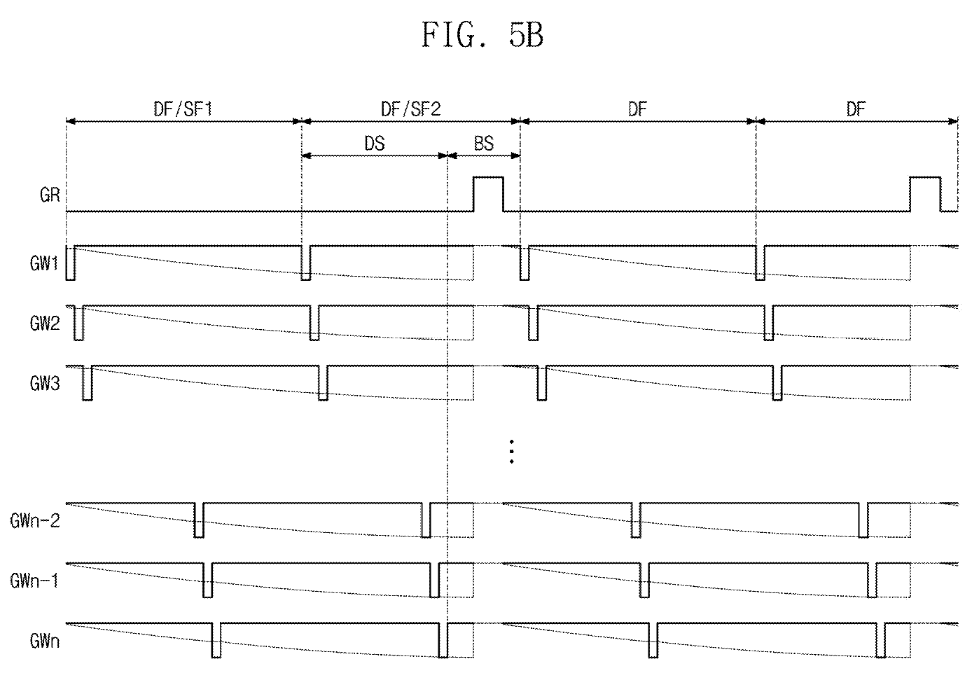

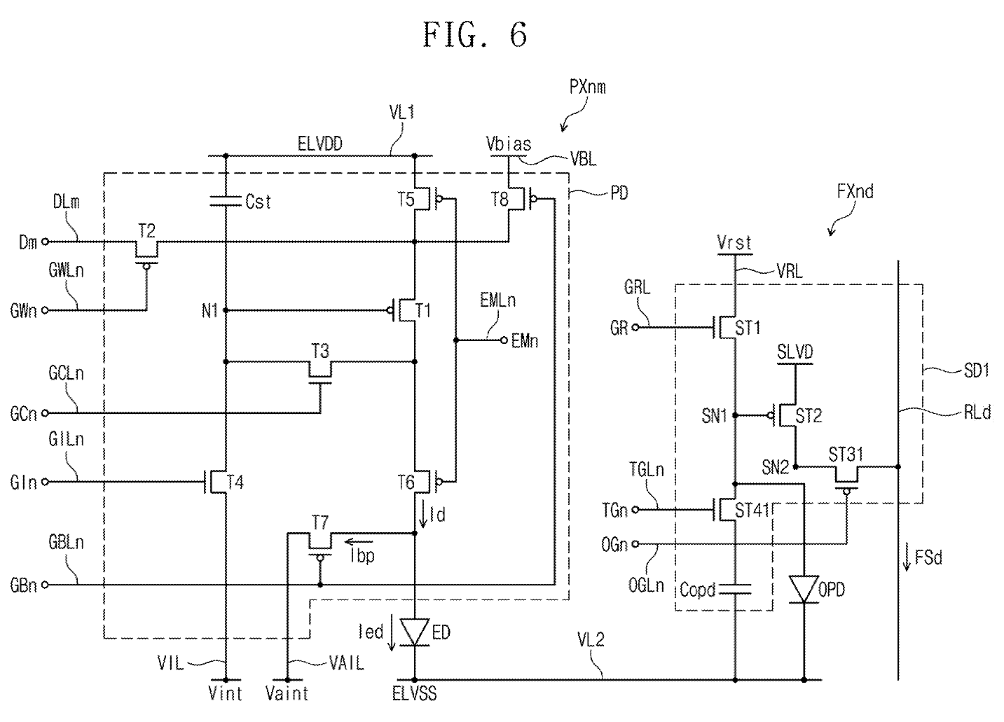

FIG. 5A is a block diagram of a connection relationship of an output transistor and a control transistor according to one or more embodiments. FIG. 5B is a timing diagram illustrating an operation of the output transistor and the control transistor shown in FIG. 5A.

Referring to FIGS. 4A, 5A, and 5B, a plurality of sensor circuits SDa may be arranged in the second direction DR2. In FIG. 5A, each of the sensor circuits SDa is illustrated as including an output transistor ST3a and a control transistor ST4a, and other components, such as the reset transistor ST1, the amplification transistor ST2, and the sensing capacitor Copd shown in FIG. 4A, are omitted. For example, the configuration of each of the sensor circuits SDa may be the same as that of the sensor circuit SD illustrated in FIG. 4A. The sensor circuits SDa may be connected to the write scan lines GWL1, GWL2, GWL3 to GWLn-2, GWLn-1, and GWLn, and may receive the write scan signals GW1, GW2, GW3 to GWn-2, GWn-1, and GWn as output control signals and light receiving control signals. Since the sensor circuits SDa operate in the same way, the description of the sensor circuit SDa located in a first row among the sensor circuits SDa is equally applied to other sensor circuits SDa.

The sensor circuit SDa may receive a first write scan signal GW1 through a first write scan line GWL1. As an example, the output transistor ST3a and the control transistor ST4a included in the sensor circuit SDa may receive the first write scan signal GW1 through the first write scan line GWL1. For example, the output transistor ST3a and the control transistor ST4a may receive a same signal, e.g., the first write scan signal GW1, and the first write scan signal GW1 may be an output control signal applied to the output transistor ST3a and a light receiving control signal applied to the control transistor ST4a.

The pixel PXnm may be driven during a plurality of display frames DF and may operate periodically based on the display frame DF. Each of the display frames DF may include a driving section DS and a blank section BS. During the driving section DS, the write scan signals GW1 to GWn may be sequentially activated and may be applied to the pixel circuit PD and the sensor circuit SDa. During the blank section BS, the reset control signal GR may be activated and may be applied to the sensor circuits. As an example, the reset control signal GR may be activated during a blank section BS of an i-th display frame DF. In FIG. 5B, an example in which the reset control signal GR is activated during a blank section BS of a second display frame DF, e.g., when i is 2, is illustrated. In the present embodiment, i is an integer greater than or equal to 1.

The sensor FXnd may operate in cycles of a first sensing frame SF1 and a second sensing frame SF2. As an example, sensing data may be accumulated at the first sensing node SN1 during the first sensing frame SF1, and the sensing data may be output to the read-out line RLd during the second sensing frame SF2. The first sensing frame SF1 may correspond to a first display frame DF among the display frames DF, and the second sensing frame SF2 may correspond to the second display frame DF among the display frames DF.

Responsive to the reset control signal GR, the reset transistor ST1 may be activated, and the reset voltage Vrst applied through the reset voltage line VRL may be applied to the first sensing node SN1 via the reset transistor ST1. As an example, the reset voltage Vrst may have a voltage level higher than that of the second driving voltage ELVSS.

The output transistor ST3a and the control transistor ST4a may be different types of transistor. As an example, the output transistor ST3a may be a P-type transistor, and the control transistor ST4a may be an N-type transistor. However, the disclosure may not be limited thereto or thereby, and the output transistor ST3a may be an N-type transistor, and the control transistor ST4a may be a P-type transistor. When the output transistor ST3a is turned on in response to the first write scan signal GW1, the control transistor ST4a may be turned off in response to the first write scan signal GW1. On the other hand, when the output transistor ST3a is turned off in response to the first write scan signal GW1, the control transistor ST4a may be turned on in response to the first write scan signal GW1.

In the timing diagram of FIG. 5B, a dotted line represents the electric potential of the first sensing node SN1. When the light receiving element OPD is exposed to external light, the amount of current flowing through the light receiving element OPD may vary depending on the amount of light incident into the light receiving element OPD. When the control transistor ST4a is turned on, the charges may be discharged from the sensing capacitor Copd in response to the current flowing through the light receiving element OPD. In this case, the discharge of the charges from the sensing capacitor Copd may change the electric potential of the first sensing node SN1, and the electric potential of the sensing signal FSd may be determined according to the electric potential of the first sensing node SN1. Hereinafter, the process in which the charges are discharged from the sensing capacitor Copd and the electric potential of the first sensing node SN1 varies may be referred to as a process of accumulating the sensing data. FIG. 5B illustrates the electric potential of the first sensing node SN1, which gradually decreases.

When the control transistor ST4a is turned off, the charges may not be discharged from the sensing capacitor Copd. In this case, the electric potential of the first sensing node SN1 may be maintained at a constant value.

According to the disclosure, when the output transistor ST3a outputs the sensing signal FSd in response to the first write scan signal GW1, noise induced by coupling with the first write scan signal GW1 may be introduced into the sensing data during the process of accumulating the sensing data at the first sensing node SN1. According to the disclosure, during the process in which the output transistor ST3a outputs the sensing signal FSd in response to the first write scan signal GW1, the control transistor ST4a may be turned off to stop the accumulation of the sensing data at the first sensing node SN1. Accordingly, when the output transistor ST3a outputs the sensing signal FSd, data from which the noise is removed or reduced may be obtained, and thus, the display device with improved sensing sensitivity may be provided.

FIG. 6 is a circuit diagram of a pixel and a sensor according to one or more embodiments.

Referring to FIG. 6, a sensor circuit SD1 may include a reset transistor ST1, an amplification transistor ST2, an output transistor ST31, a control transistor ST41, and a sensing capacitor Copd. In FIG. 6, the output transistor ST31 and the control transistor ST41 are illustrated as being different types of transistor, however, the present embodiment may not be limited thereto or thereby, and the output transistor ST31 and the control transistor ST41 may be the same type of transistor. For example, the output transistor ST31 and the control transistor ST41 may both be N-type transistors or P-type transistors. The output transistor ST31 may receive an output control signal OGn through an output control line OGLn, and the control transistor ST41 may receive a light receiving control signal TGn through a light receiving control line TGLn.

According to the circuit diagram of FIG. 4A, the output transistor ST3 and the control transistor ST4 operate in response to a same signal. In contrast, according to the circuit diagram of FIG. 6, the output transistor ST31 operates in response to an output control signal, and the control transistor ST41 operates in response to a light receiving control signal that becomes inactive when the output control signal is activated. Except for this difference, the circuit diagram of FIG. 6 has a configuration similar to that of FIG. 4A. Accordingly, in the circuit diagram of FIG. 6, the same reference numerals denote the same elements in the circuit diagram of FIG. 4A, and thus, detailed descriptions of the same elements will be omitted.

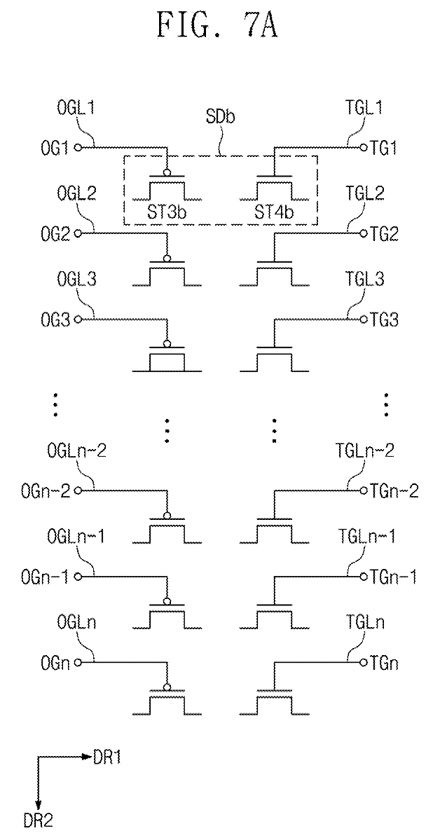

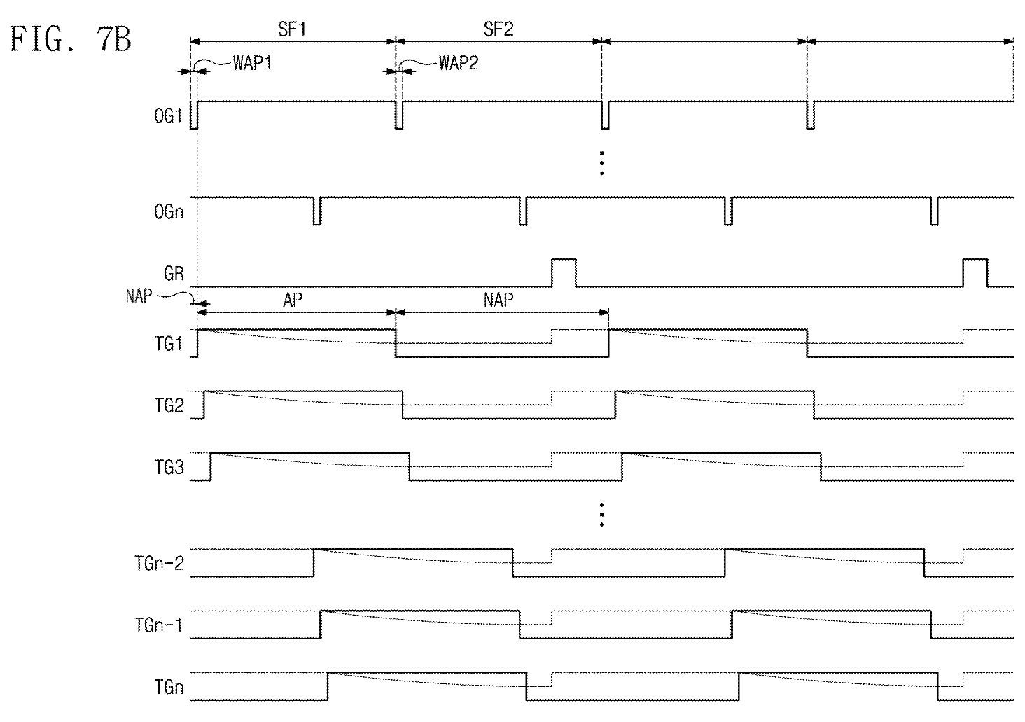

FIG. 7A is a block diagram of a connection relationship of an output transistor and a control transistor according to one or more embodiments. FIG. 7B is a timing diagram illustrating an operation of the output transistor and the control transistor shown in FIG. 7A.

Referring to FIGS. 6, 7A, and 7B, a plurality of sensor circuits SDb may be arranged in the second direction DR2. In FIG. 7A, each of the sensor circuits SDb is illustrated as including an output transistor ST3b and a control transistor ST4b, and the other components, such as the reset transistor ST1, the amplification transistor ST2, and the sensing capacitor Copd, are omitted. For example, the configuration of each of the sensor circuits SDb is similar to that of the sensor circuit SD1 illustrated in FIG. 6. The sensor circuits SDb may receive output control signals OG1, OG2, OG3 to OGn-2, OGn-1, and OGn via output control lines OGL1, OGL2, OGL3 to OGLn-2, OGLn-1, and OGLn and may receive light receiving control signals TG1, TG2, TG3 to TGn−2, TGn-1, and TGn via light receiving control lines TGL1, TGL2, TGL3 to TGLn-2, TGLn-1, and TGLn. As an example, the output control signals OG1 to OGn may be the same as the write scan signals GW1 to GWn (refer to FIG. 5A). Since the sensor circuits SDb operate in the same way, the description of the sensor circuit SDb in a first row among the sensor circuits SDb is equally applied to other sensor circuits SDb.

The output transistor ST3b of the sensor circuit SDb may be connected to a first output control line OGL1 and may receive a first output control signal OG1 through the first output control line OGL1. The control transistor ST4b of the sensor circuit SDb may be connected to a first light receiving control line TGL1 and may receive a first light receiving control signal TG1 through the first light receiving control line TGL1.

The sensor circuit SDb may operate in cycles of a first sensing frame SF1 and a second sensing frame SF2. During each of the first sensing frame SF1 and the second sensing frame SF2, the output control signals OG1 to OGn may be sequentially activated. The first output control signal OG1 may include a first activation period WAP1 during the first sensing frame SF1 and a second activation period WAP2 during the second sensing frame SF2. During the first sensing frame SF1, the light receiving control signals TG1 to TGn may be sequentially activated. The first light receiving control signal TG1 may include an activation period AP and a portion of a non-activation period NAP during the first sensing frame SF1 and may include the remaining portion of the non-activation period NAP during the second sensing frame SF2, however, the disclosure may not be limited thereto or thereby. According to an embodiment, timings at which the first light receiving control signal TG1 is activated and deactivated may be freely set to achieve the objectives of the disclosure.

As an example, during the first sensing frame SF1, the first activation period WAP1 of the first output control signal OG1 may overlap the non-activation period NAP of the first light receiving control signal TG1, and during the second sensing frame SF2, the second activation period WAP2 of the first output control signal OG1 may overlap the non-activation period NAP of the first light receiving control signal TG1. When the output control signals OG1 to OGn are activated during the first and second sensing frames SF1 and SF2, the first light receiving control signal TG1 may be deactivated, and thus, the control transistor ST4b may be turned off. Accordingly, the process of accumulating sensing data at the first sensing node SN1 may be interrupted, and when the output transistor ST3b outputs a sensing signal FSd, data from which noise is removed or reduced may be obtained.

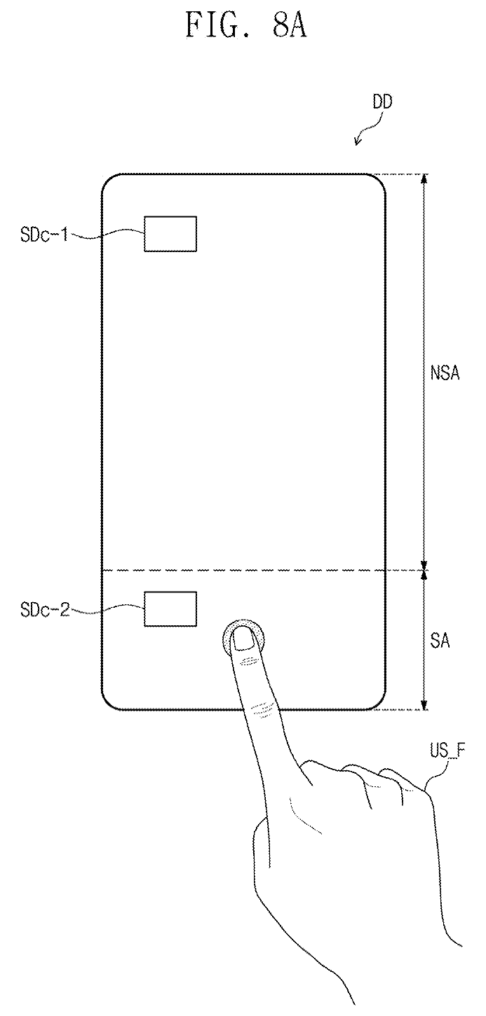

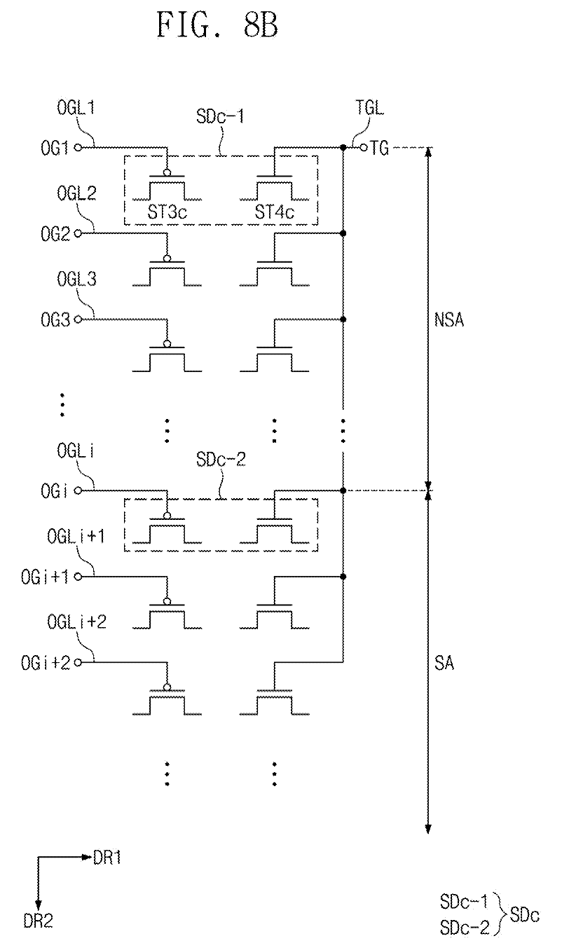

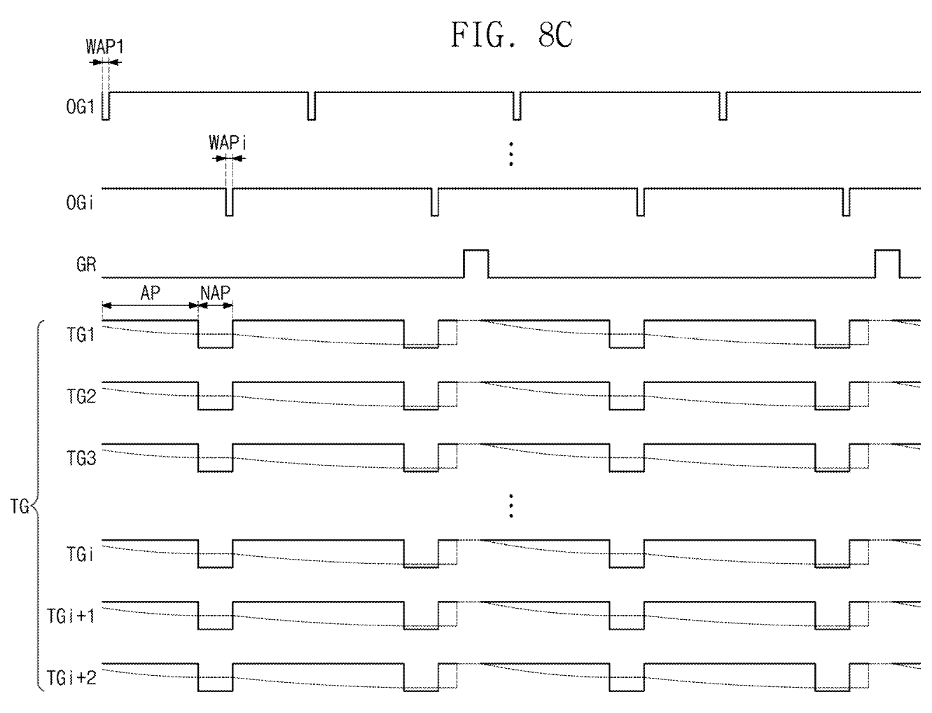

FIG. 8A is a plan view of a display device according to one or more embodiments. FIG. 8B is a block diagram of a connection relationship of an output transistor and a control transistor according to one or more embodiments. FIG. 8C is a timing diagram illustrating an operation of the output transistor and the control transistor shown in FIG. 8B.

Referring to FIG. 8A, the display surface IS of the display device DD (refer to FIG. 1) may be divided into a sensing area SA and a non-sensing area NSA. The sensing area SA is an area where a user inputs fingerprint information by touching a screen with the user’s finger US_F. FIG. 8A illustrates an example in which the non-sensing area NSA and the sensing area SA are disposed at an upper area and a lower area of the display device DD, respectively, however, the disclosure may not be limited thereto or thereby. According to an embodiment, the sensing area SA may be disposed at a central area of the display device DD, and a position of the sensing area SA may be freely set to any location where the user is able to input the fingerprint information.

Referring to FIGS. 8B and 8C, each of a plurality of sensor circuits SDc may be arranged in the second direction DR2. The configuration of each of the sensor circuits SDc is similar to that of the sensor circuit SD1 shown in FIG. 6. The sensor circuits SDc may receive output control signals OG1, OG2, OG3 to OGi, OGi+1, and OGi+2 through output control lines OGL1, OGL2, OGL3 to OGLi, OGLi+1, and OGLi+2 and may receive a light receiving control signal TG through a light receiving control line TGL. For example, each of the sensor circuits SDc may be commonly connected to a single light receiving control line TGL and may commonly receive the light receiving control signal TG through the light receiving control line TGL. Accordingly, during an activation period AP of the light receiving control signal TG, control transistors ST4c included in each of the sensor circuits SDc may be commonly turned on, and during a non-activation period NAP of the light receiving control signal TG, the control transistors ST4c included in each of the sensor circuits SDc may be commonly turned off. As an example, the output control signals OG1 to OGi+2 may be a same signals as the write scan signals GW1 to GWn illustrated in FIG. 5A.

The sensor circuits SDc may include a first sensor circuit SDc-1 disposed in the non-sensing area NSA and a second sensor circuit SDc-2 disposed in the sensing area SA. Since the sensor circuits disposed in the non-sensing area NSA operate in the same way, the description of the first sensor circuit SDc-1 located in a first row of the non-sensing area NSA may be equally applied to the other sensor circuits disposed in the non-sensing area NSA. Likewise, since the sensor circuits disposed in the sensing area SA operate in a similar manner, the description of the second sensor circuit SDc-2 located in a first row of the sensing area SA may be equally applied to the other sensor circuits disposed in the sensing area SA.

An output transistor ST3c of the first sensor circuit SDc-1 may be connected to a first output control line OGL1 and may receive a first output control signal OG1 through the first output control line OGL1. A control transistor ST4c of the first sensor circuit SDc-1 may be connected to the light receiving control line TGL and may receive the light receiving control signal TG through the light receiving control line TGL. An output transistor ST3c of the second sensor circuit SDc-2 may be connected to an i-th output control line OGLi and may receive an i-th output control signal OGi through the i-th output control line OGLi. A control transistor ST4b of the second sensor circuit SDc-2 may be connected to the light receiving control line TGL and may receive the light receiving control signal TG through the light receiving control line TGL.

Since each of the sensor circuits SDc is connected through the single light receiving control line TGL, the control transistors ST4c included in the sensor circuits SDc may be commonly connected to the light receiving control line TGL. Accordingly, the control transistors ST4c included in the sensor circuits SDc may commonly receive the light receiving control signal TG through the light receiving control line TGL.

As an example, an activation period WAP1 of the first output control signal OG1 may overlap the activation period AP of the light receiving control signal TG, and an activation period WAPi of the i-th output control signal OGi may overlap the non-activation period NAP of the light receiving control signal TG. For example, the activation periods of the output control signals applied to the sensor circuits disposed in the non-sensing area NSA may overlap the activation period AP of the light receiving control signal TG, and the activation periods of the output control signals applied to the sensor circuits disposed in the sensing area SA may overlap the non-activation period NAP of the light receiving control signal TG. When sensing data with respect to the sensing area SA is output, the light receiving control signal TG may be deactivated, and thus, the sensing data may not be accumulated. Accordingly, the sensing data from which noise is removed or reduced may be obtained from the sensing area SA, so the noise may be selectively removed or reduced depending on the area.

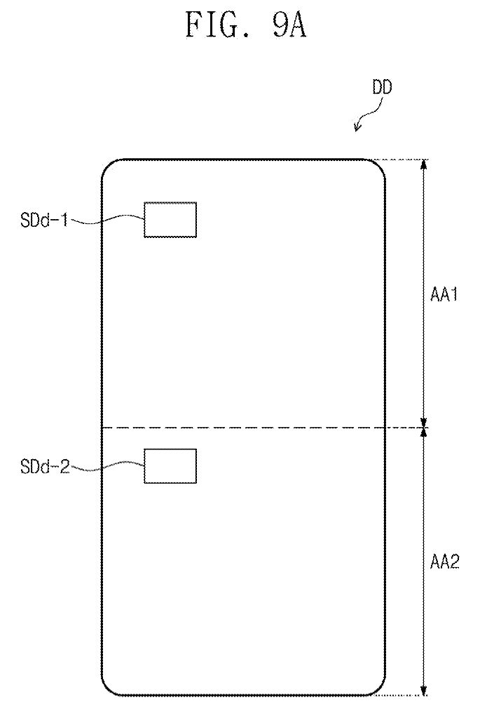

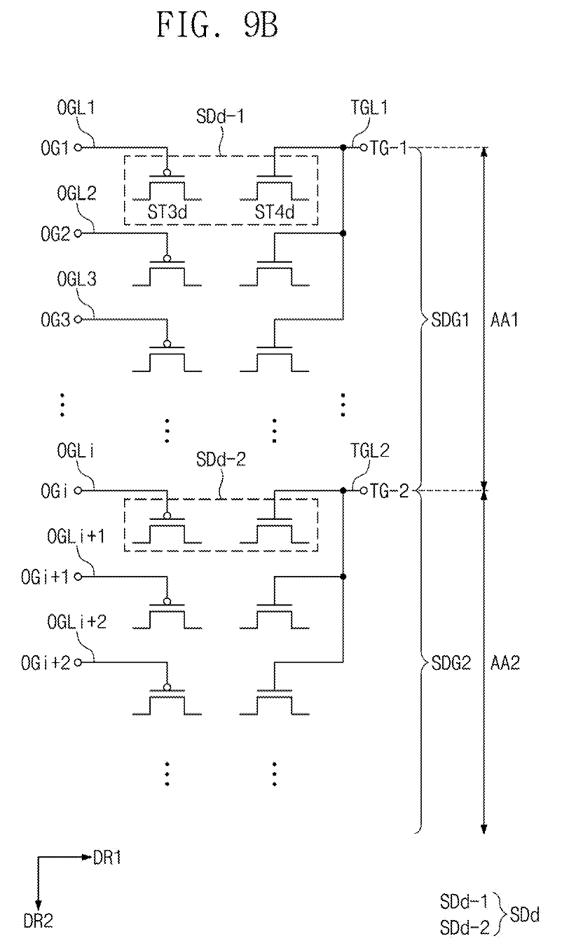

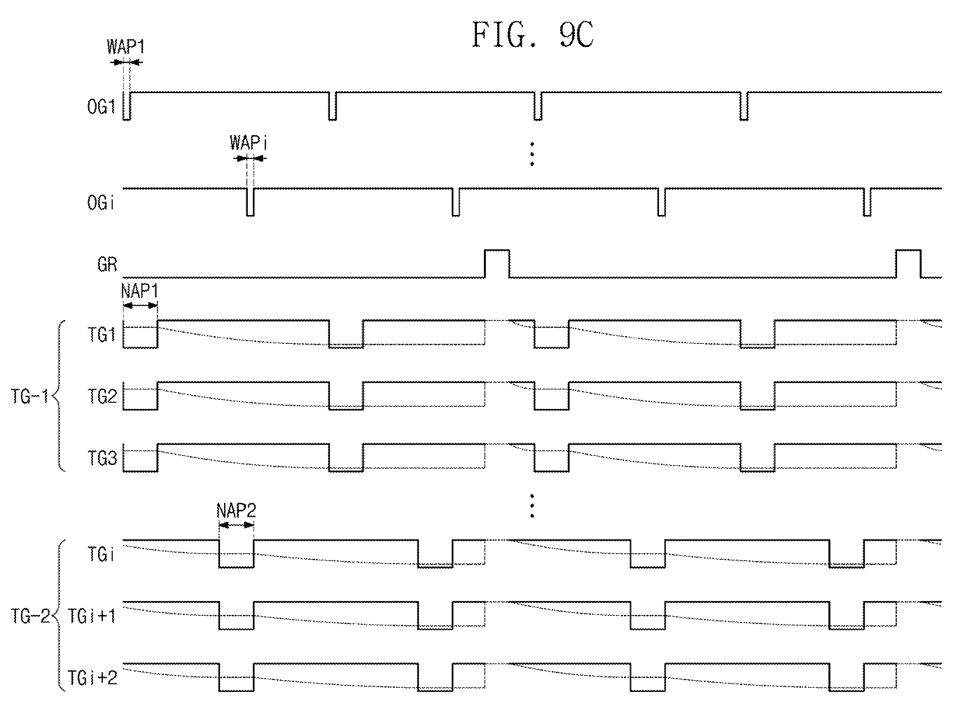

FIG. 9A is a plan view of a display device according to one or more embodiments. FIG. 9B is a block diagram of a connection relationship of an output transistor and a control transistor according to one or more embodiments. FIG. 9C is a timing diagram illustrating an operation of the output transistor and the control transistor shown in FIG. 9B.

Referring to FIGS. 9A, 9B, and 9C, each of a plurality of sensor circuits SDd may be arranged in the second direction DR2. The configuration of each of the sensor circuits SDd is similar to that of the sensor circuit SD1 illustrated in FIG. 6. The sensor circuits SDd may receive output control signals OG1, OG2, OG3 to OGi, OGi+1, and OGi+2 through output control lines OGL1, OGL2, OGL3 to OGLi, OGLi+1, and OGLi+2 and may receive light receiving control signals TG-1 and TG-2 through light receiving control lines TGL1 and TGL2.

The sensor circuits SDd may include a first sensor circuit group SDG1 and a second sensor circuit group SDG2. The first sensor circuit group SDG1 may receive a first light receiving control signal TG-1 through a first light receiving control line TGL1, and the second sensor circuit group SDG2 may receive a second light receiving control signal TG-2 through a second light receiving control line TGL2. As an example, the first sensor circuit group SDG1 may be disposed in a first area AA1 of the display device DD, and the second sensor circuit group SDG2 may be disposed in a second area AA2 of the display device DD. However, the disclosure may not be limited thereto or thereby, and the display device DD may be divided into three or more areas. In this case, the sensor circuits may be grouped into three or more sensor circuit groups, and each sensor circuit group may be disposed in a corresponding area.

The first sensor circuit group SDG1 may include a first sensor circuit SDd-1 disposed in a first row of the first sensor circuit group SDG1, and the second sensor circuit group SDG2 may include a second sensor circuit SDd-2 disposed in a first row of the second sensor circuit group SDG2. Since each of the sensor circuits disposed in the first area AA1 operates in the same manner as the first sensor circuit SDd-1, the description of the first sensor circuit SDd-1 may be equally applied to the other sensor circuits disposed in the first area AA1. Likewise, since each of the sensor circuits disposed in the second area AA2 operate in the same manner as the second sensor circuit SDd-2, the description of the second sensor circuit SDd-2 may be equally applied to the other sensor circuits disposed in the second area AA2.

An output transistor ST3d of the first sensor circuit SDd-1 may be connected to a first output control line OGL1 and may receive a first output control signal OG1 through the first output control line OGL1.A control transistor ST4d of the first sensor circuit SDd-1 may be connected to a first light receiving control line TGL1 and may receive a first light receiving control signal TG-1 through the first light receiving control line TGL1. An output transistor ST3d of the second sensor circuit SDd-2 may be connected to an i-th output control line OGLi and may receive an i-th output control signal OGi through the i-th output control line OGLi. A control transistor ST4d of the second sensor circuit SDd-2 may be connected to a second light receiving control line TGL2 and may receive a second light receiving control signal TG-2 through the second light receiving control line TGL2.

As an example, an activation period WAP1 of the first output control signal OG1 may overlap a first non-activation period NAP1 of the first light receiving control signal TG-1, and an activation period WAPi of the i-th output control signal OGi may overlap a second non-activation period NAP2 of the second light receiving control signal TG-2. In other words, activation periods of the output control signals applied to the first sensor circuit group SDG1 disposed in the first area AA1 may overlap the first non-activation period NAP1 of the first light receiving control signal TG-1 applied to the first sensor circuit group SDG1, and activation periods of the output control signals applied to the second sensor circuit group SDG2 disposed in the second area AA2 may overlap the second non-activation period NAP2 of the second light receiving control signal TG-2 applied to the second sensor circuit group SDG2. When outputting sensing data with respect to each of the first area AA1 and the second area AA2, the light receiving control signal applied to the corresponding area may be deactivated, and thus, the sensing data may not be accumulated. Accordingly, the sensing data from which noise is removed or reduced may be obtained from each of the first area AA1 and the second area AA2, so the noise may be removed or reduced across the entire area of the display device DD.

The display devices DD described above may be applied to various electronic devices. An electronic device according to one or more embodiments may include at least one of the display devices DD and may further include a module or device having additional functions in addition to the display device DD.

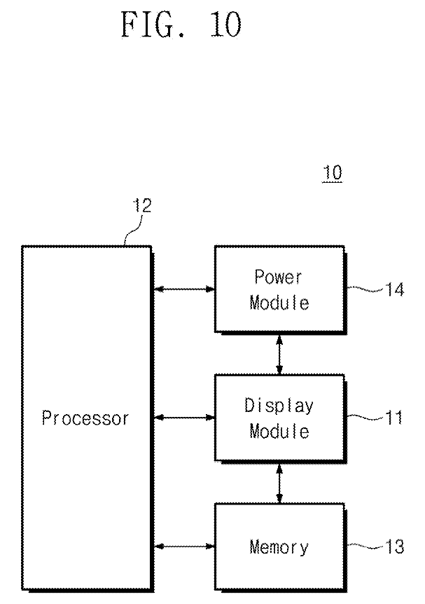

FIG. 10 is a block diagram illustrating an electronic device according to one or more embodiments. Referring to FIG. 10, an electronic device 10 may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller. The processor 12 may control the operation of the display device according to embodiments of the disclosure.

The memory 13 may store data information required for the operation of the processor 12 or the display module 11. When the processor 12 executes an application stored in the memory 13, an image data signal and/or an input control signal may be transmitted to the display module 11, and the display module 11 may process the received signals to output image information through a display screen.

The power module 14 may include a power supply module, such as a power adapter or a battery device, and a power conversion module that converts power supplied by the power supply module to generate power required for the operation of the electronic device 10.

The electronic device 10 may include the display device according to the embodiments, and at least one of components of the electronic device 10 may be included in the display device according to embodiments. In addition, among individual modules that are functionally included within a single module, some may be included in the display device while others may be provided separately from the display device. As an example, the display device may include the display module 11, and the processor 12, the memory 13, and the power module 14 may be provided as separate devices within the electronic device 10, rather than being included in the display device.

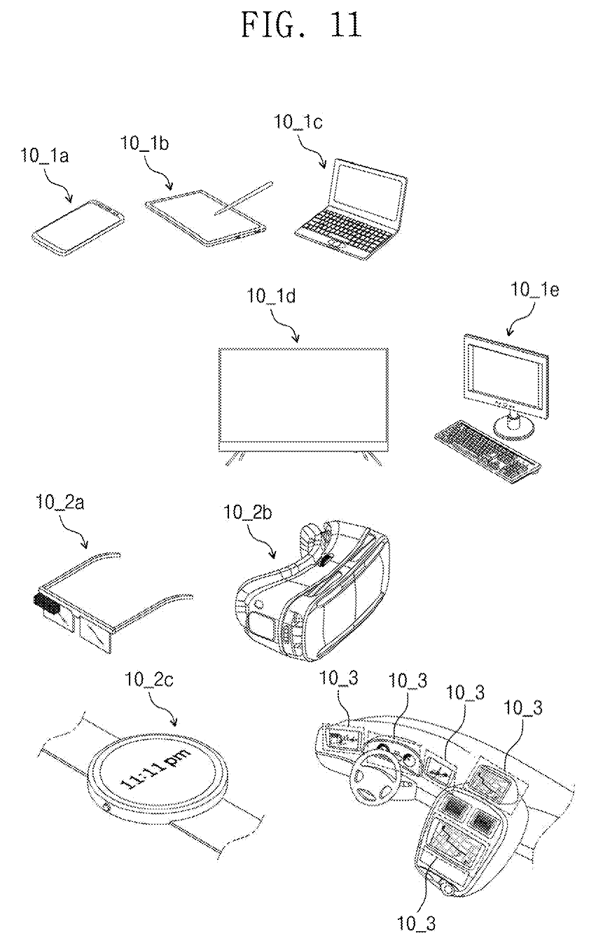

FIG. 11 is a schematic view illustrating electronic devices according to one or more embodiments.

Referring to FIG. 11, various electronic devices to which at least one of the display devices DD according to the above embodiments is applied may include not only an electronic device for displaying images, such as a smartphone 10_1a, a tablet PC 10_1b, a laptop computer 10_1c, a television 10_1d, a desktop monitor 10_1e, etc., but also a wearable electronic device including a display module, such as a smart glasses 10_2a, a head-mounted display 10_2b, a smartwatch 10_2c, etc., and an in-vehicle electronic device 10_3 including a display module, such as an instrument panel, a center fascia, a dashboard-mounted center information display (CID), a room mirror display, etc.

Although the embodiments of the disclosure have been described, it is understood that the disclosure should not be limited to these embodiments but various changes and modifications can be made by one ordinary skilled in the art within the spirit and scope of the disclosure as hereinafter claimed. Therefore, the disclosed subject matter may not be limited to any single embodiment described herein, and the scope of the disclosure shall be determined according to the attached claims.

What is claimed is:

1. A display device comprising:
pixel circuits and sensor circuits; and
light emitting elements respectively connected to the pixel circuits and light receiving elements respectively connected the sensor circuits,
wherein each of the sensor circuits comprises:
a sensing capacitor;
a reset transistor connected between a reset voltage line and a first sensing node and configured to operate based on a reset control signal;
an amplification transistor connected to a second sensing node and configured to receive a sensing driving voltage;
an output transistor connected between the second sensing node and a read-out line and configured to operate based on an output control signal; and
a control transistor connected between the first sensing node and the sensing capacitor and configured to operate based on a light receiving control signal,
wherein an active period of the output control signal applied to at least one of the sensor circuits overlaps a non-active period of the light receiving control signal.

2. The display device of claim 1, wherein the output control signal is a same signal as the light receiving control signal.

3. The display device of claim 1, wherein the output transistor and the control transistor are different types of transistor, and based on the output transistor being turned on, the control transistor is configured to be turned off.

4. The display device of claim 1, wherein the output transistor is connected to an output control line and configured to receive the output control signal through the output control line, and the control transistor is connected to a light receiving control line and configured to receive the light receiving control signal through the light receiving control line.

5. The display device of claim 4, wherein the active period of the output control signal overlaps the non-active period of the light receiving control signal during a first sensing frame and a second sensing frame.

6. The display device of claim 5, wherein the sensor circuits are configured to accumulate sensing data during the first sensing frame and output the sensing data to the read-out line during the second sensing frame.

7. The display device of claim 1, wherein the control transistors are commonly connected to a light receiving control line, and the control transistors are configured to commonly receive the light receiving control signal through the light receiving control line.

8. The display device of claim 1, wherein the display device comprises a sensing area and a non-sensing area, and
wherein an active period of an output control signal applied to a first sensor circuit in the non-sensing area among the sensor circuits overlaps an active period of a light receiving control signal applied to the first sensor circuit, and an active period of an output control signal applied to a second sensor circuit in the sensing area among the sensor circuits overlaps a non-active period of a light receiving control signal applied to the second sensor circuit.

9. The display device of claim 1, wherein the sensor circuits comprise a first sensor circuit group and a second sensor circuit group, the first sensor circuit group is connected to a first light receiving control line to receive a first light receiving control signal, and the second sensor circuit group is connected to a second light receiving control line to receive a second light receiving control signal.

10. The display device of claim 9, wherein the first light receiving control signal has a first non-active period, an active period of an output control signal applied to the first sensor circuit group overlaps the first non-active period, the second light receiving control signal has a second non-active period different from the first non-active period, and an active period of an output control signal applied to the second sensor circuit group overlaps the second non-active period.

11. The display device of claim 10, wherein the display device comprises a first area and a second area, the first sensor circuit group is in the first area, and the second sensor circuit group is in the second area.

12. The display device of claim 1, wherein each of the pixel circuits comprises:
a driving transistor connected between a light emitting element, among the light emitting elements, and a first driving voltage line; and
a switching transistor connected to the driving transistor and configured to receive a data voltage and a scan signal.

13. The display device of claim 12, wherein the scan signal is a same signal as the output control signal.

14. The display device of claim 13, wherein the display device operates during a plurality of display frames, each of the plurality of display frames comprises a driving section and a blank section, and the scan signal is sequentially activated during the driving section.

15. The display device of claim 14, wherein the reset control signal is activated during the blank section of an i-th display frame, a reset voltage applied through the reset voltage line is applied to the first sensing node through the reset transistor, and the i is an integer greater than or equal to 1.

16. A display device comprising:
a pixel circuit;
a sensor circuit;
a light emitting element connected to the pixel circuit; and
a light receiving element connected the sensor circuit,
wherein the sensor circuit comprises:
a sensing capacitor;
a reset transistor connected between a reset voltage line and a first sensing node and configured to operate based on a reset control signal;
an amplification transistor connected to a second sensing node and configured to receive a sensing driving voltage;
an output transistor connected between the second sensing node and a read-out line and configured to operate based on an output control signal; and
a control transistor connected between the first sensing node and the sensing capacitor and configured to operate based on a light receiving control signal,
wherein the control transistor is configured to be turned off when the output transistor outputs a sensing signal to the read-out line based on the output control signal.

17. The display device of claim 16, wherein the control transistor is one of a p-type transistor and an n-type transistor and the output transistor is the other of the p-type transistor and the n-type transistor.

18. The display device of claim 16, wherein the control transistor and the output transistor are configured to receive a common gate input signal.

19. The display device of claim 16, wherein the light emitting element and the light receiving element are configured to receive a common driving voltage.

20. An electronic device comprising:
the display device of claim 1; and
a processor configured to control an operation of the display device.
